(19) United States
(12) Patent Application Publication
(10) Pub. No.: US 2007/0069261 A1
(43) Pub. Date: Mar. 29, 2007

(54) CMOS image sensor and a method for manufacturing the same

(76) Inventor: Joon Hwang, Cheongju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/527,939

(22) Filed: Sep. 26, 2006

(30) Foreign Application Priority Data
Sep. 28, 2005 (KR) 10-2005-0090264

(51) Int. Cl. H01L 31/113

(52) U.S. Cl. 257/292

(57) ABSTRACT

A CIS and a method for manufacturing the same are provided. The CIS includes a photodiode formed on a substrate; an interlayer insulation layer formed on an entire surface of the substrate including the photodiode; a color filter layer formed on the interlayer insulation layer to pass light in a specific wavelength range; and a microlens formed on the color filter layer, where the microlens includes a predetermined opened region in a portion of the microlens corresponding to the location of the photodiode.

### RELATED APPLICATION

This application claims the benefit under 35 U.S.C. §119(e), of Korean Patent Application Number 10-2005-0090264 filed Sep. 28, 2005, which is incorporated herein by reference in its entirety.

### FIELD OF THE INVENTION

The present invention relates to a CMOS image sensor and a method for manufacturing the same.

### BACKGROUND OF THE INVENTION

In general, an image sensor is a semiconductor device that converts an optical image into an electrical signal. The image sensors are generally classified into charge coupled devices (CCDs) and complementary metal oxide silicon (CMOS) image sensors (CISs).

The CIS includes a photodiode that can sense a projected light and a CMOS logic circuit processing the sensed light into an electric signal for data. As the amount of light in the photodiode increases, the photosensitivity of the image sensor improves.

To increase the photosensitivity, one technique is to increase a fill factor (a ratio of a photodiode area to an entire area of the image sensor). Another is a technique in which the path of light incident into a region other than a photodiode is changed to focus the light on the photodiode.

A typical example of the focusing technology includes a microlens formation. In the microlens formation, a convex microlens is formed of an excellent light transmission material on the photodiode such that more incident light may be projected onto the photodiode region by refracting the incident light.

In this case, the light parallel to an optical axis of the microlens is refracted through the microlens, and thus the focus of the microlens is formed at a predetermined position of the optical axis.

Hereinafter, a related art CIS will be described with reference to FIG. 1.

FIG. 1 is a sectional view of the related art CIS.

As illustrated in FIG. 1, in the related art CIS, a photodiode 11 is formed on a semiconductor substrate (not shown). An interlayer insulation layer 12 is formed on an entire surface of the semiconductor substrate including the photodiode 11.

A protective layer 13 is formed on the interlayer insulation layer 12. An RGB color filter layer 14 for passing light in a specific wavelength range is formed on the protective layer 13. A planarization layer 15 is formed on an entire surface of the semiconductor substrate including the color filter layer 14. Then, a microlens 16 in a convex shape having a predetermined curvature is formed on the planarization layer 15.

In a process of manufacturing the related art CIS, the microlens 16 for enhancing the light focusing efficiency is an important factor determining characteristics of the image sensor.

Light incident to the CIS is concentrated through the microlens 16, filtered through color filter 14 layer, and incident into the photodiode 11 below the color filter layer 14.

Lights \textcircled{1}, \textcircled{2}, \textcircled{3}, and \textcircled{4} incident to the CIS of FIG. 1 must pass through microlens 16 to reach the photodiode 11, which receives the light at a reduced light transmittance due to the microlens 16. Lights \textcircled{1} and \textcircled{2} are incident the microlens 16 within photodiode region A and lights \textcircled{3} and \textcircled{4} are incident the microlens 16 outside the photodiode region A. The microlens 16 is needed to direct lights \textcircled{3} and \textcircled{4} into an inside of the photodiode 11.

However, the related art CIS has following problems.

That is, since the incident light is absorbed in the microlens while passing through the microlens, the light energy incident into the photodiode region A of FIG. 1 occupying most of light receiving region decreases. Thus, the sensitivity of the image sensor decreases.

### SUMMARY OF THE INVENTION

Accordingly, the present invention is directed to a CIS and a method for manufacturing the same that addresses and/or substantially obviates one or more problems, limitations, and/or disadvantages of the related art.

An object of the present invention is to provide a CIS that can maximize a light energy incident to a photodiode to improve the sensitivity of an image sensor and a method for manufacturing the same.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a CIS including: a photodiode formed on a substrate; an interlayer insulation layer formed on an entire surface of the substrate including the photodiode; a color filter layer formed on the interlayer insulation layer to pass light in a specific wavelength range; and a microlens formed on the color filter layer, the microlens having a predetermined opened region in a portion of the microlens corresponding to the location of the photodiode.

In another aspect of the present invention, there is provided a method for manufacturing a CIS including: forming an interlayer insulation layer on a substrate having a photodiode formed thereon; forming a color filter layer on the interlayer insulation layer; forming a microlens corresponding to the photodiode on the color filter layer; and selectively removing a portion of the microlens in a region corresponding to the location of the photodiode to form an opening.

In a further another aspect of the present invention, there is provided a method for manufacturing a CIS including: forming an interlayer insulation layer on a substrate having a photodiode formed thereon; forming a color filter layer on the interlayer insulation layer; forming an insulation layer pattern corresponding to the photodiode on the color filter layer; forming sidewalls of microlens material on both sides of the insulation layer pattern; and removing the insulation layer pattern to form a microlens having an opening at a region corresponding to the location of the photodiode.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a sectional view of a related art CIS;

FIG. 2 is a sectional view of a CIS according to an embodiment of the present invention;

FIGS. 3 to 7 are sectional views illustrating a method for manufacturing a CIS according to a first embodiment of the present invention; and

FIGS. 8 to 11 are sectional views illustrating a method for manufacturing a CIS according to a second embodiment of the present invention.

### DETAILED DESCRIPTION OF THE INVENTION

Reference will now be made in detail to the preferred embodiments of the present invention, examples of which are illustrated in the accompanying drawings.

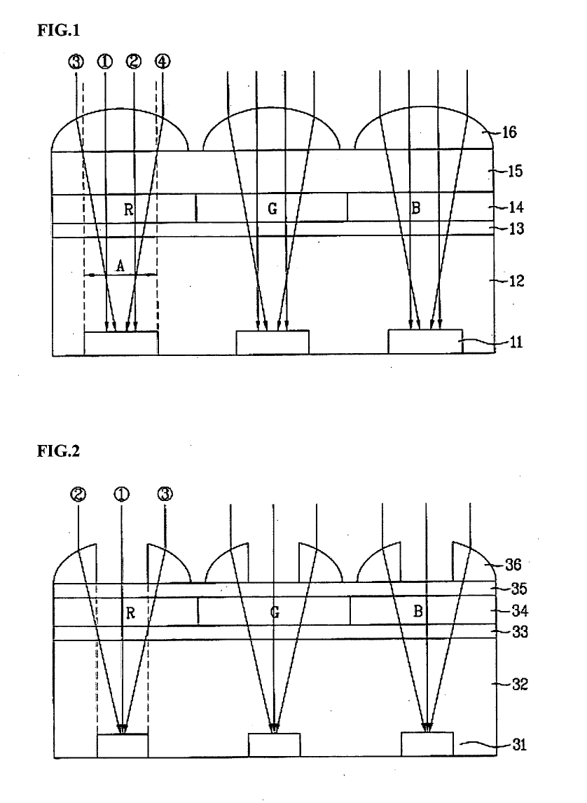

FIG. 2 is a sectional view of a CIS according to an embodiment of the present invention.

As illustrated in FIG. 2, a photodiode 31 for generating charges according to an amount of light incident to a semiconductor substrate (not shown) can be formed on the semiconductor substrate. An interlayer insulation layer 32, and a protective layer 33 can be sequentially formed on an entire surface of the semiconductor substrate including the photodiode 31.

An RGB color filter layer 34 for passing light in a specific wavelength range can be formed on the protective layer 33. A planarization layer 35 can be formed on an entire surface of the semiconductor substrate including the color filter layer 34.

A microlens 36 can be formed on the planarization layer 35. The microlens 36 is configured to have an opened portion corresponding to the position/location of the photodiode 31.

Although not shown in the drawings, a light blocking layer for preventing light from being incident to a region other than the photodiode region can also be formed in the interlayer insulation layer 32.

Because the microlens 36 has an opening corresponding to the photodiode, it can minimize the loss of light incident to the photodiode 31.

In one embodiment, the opening can have a width identical to that of the photodiode 31. In a specific embodiment, the opening can have a thickness of 1 to 2 μm according to the width of the photodiode 31, thereby minimizing the loss of light incident into photodiode 31.

According to the CIS of the present invention, in the CIS of FIG. 2, light \textcircled{1} of incident lights \textcircled{1}, \textcircled{2}, and \textcircled{3} can be induced into the photodiode 31 without reduction of transmissivity because of the opening of the microlens 36. Lights \textcircled{2} and \textcircled{3} can be induced into the photodiode 31 because of the microlens 36.

That is, according to the CIS of the present invention, light energy outside the photodiode region is induced into the photodiode 31 through the microlens 36 and the microlens 36 is not present in the region of the photodiode to improve transmissivity. The incident light energy is maximized to improve sensitivity of the image sensor.

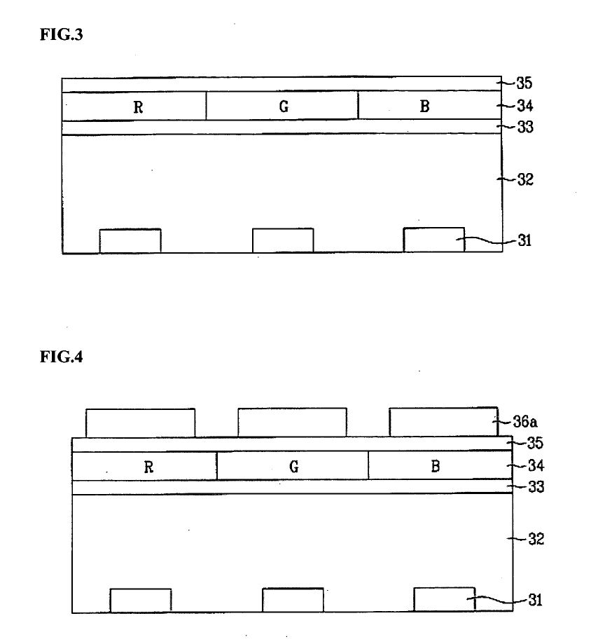

FIGS. 3 to 7 are sectional views illustrating a method for manufacturing a CIS according to a first embodiment of the present invention.

As illustrated in FIG. 3, an interlayer insulation layer 32 can be formed on a semiconductor substrate having a plurality of light detecting devices (e.g., photodiodes 31).

In an embodiment, the interlayer insulation layer 32 can be formed of multiple layers. In one embodiment, although not shown in the drawings, after one interlayer insulation layer is formed, a light blocking layer for preventing light from being incident to a region other than the photodiode 31 can be formed, and then another interlayer insulation layer can be formed thereon.

A protective layer 33 can be formed on the interlayer insulation layer 32 to protect a device from moisture and scratching.

Then, a dyeable resist can be coated on the protective layer 33, and then exposed and developed to form an RGB color filter layer 34 to filter light in each wavelength range.

A planarization layer 35 can be formed on the color filter layer 34 to obtain planarization for focal distance adjustment and formation of a lens layer.

As illustrated in FIG. 4, a microlens material layer (e.g., resist layer) can be coated on the planarization layer 35, and selectively patterned using an exposure and development process to form a microlens pattern 36a corresponding to each photodiode 31.

As illustrated in FIG. 5, the microlens pattern 36a can be reflowed to form a hemispherical microlens 36.

In one embodiment, the reflow process can be performed in a temperature range of 150 to 200° C. The reflow process can be performed using a hot plate or a furnace. The curvature of the microlens 36 varies depending on the shrinking/heating process, and therefore focusing/condensing efficiency also changes according to the curvature.

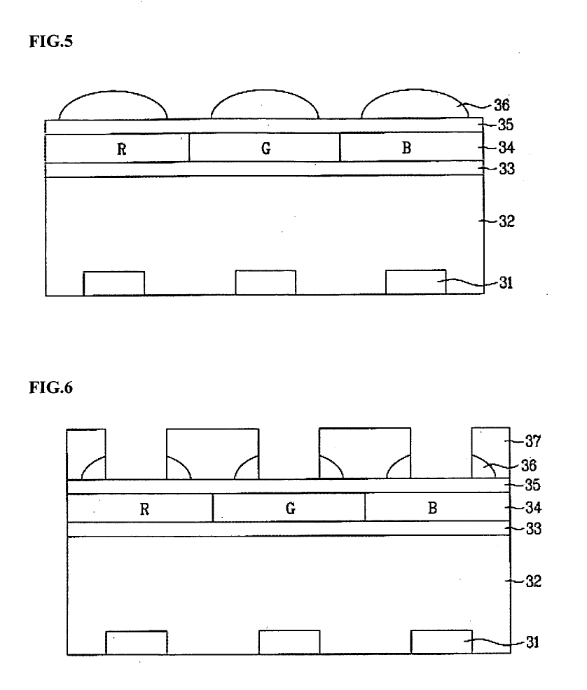

As illustrated in FIG. 6, a photosensitive film 37 can be coated on an entire surface of the microlens 36, and can be selectively patterned using an exposure and development process to expose a portion of each microlens 36.

Next, the exposed portion of each microlens 36 can be selectively etched using the patterned photosensitive film 37 as a mask.

Here, the removal width can vary according to the size of the microlens. In a specific embodiment, a width 1 to 2 μm with respect to the center can be removed from the microlens 36.

In an embodiment, the microlens 36 before having a portion selectively removed can have a larger width than the photodiode 31 it corresponds to.

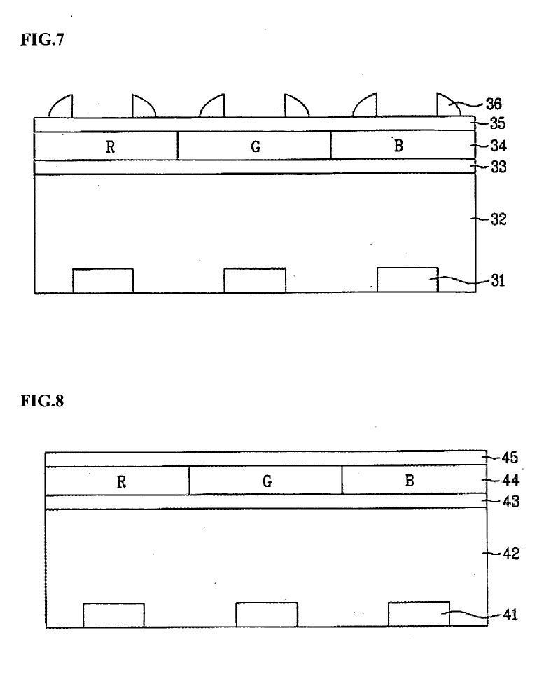

As illustrated in FIG. 7, after the patterned photosensitive film 37 is removed, ultraviolet rays can be projected onto the substrate to harden the remaining portions of microlens 36. In one embodiment, a laser can be used to project UV rays onto the surface. For embodiments where the microlens 36 is hardened using the projected ultraviolet rays, the microlens 36 can maintain the optimized radius of curvature.

According to a method for manufacturing the CIS in the first embodiment, light energy outside the photodiode region can be induced into the photodiode through the microlens. The microlens in the region of the photodiode can be removed to improve light transmissivity. Therefore, the incident light energy can be maximized to improve the sensitivity of an image sensor.

FIGS. 8 to 11 are sectional views illustrating a method for manufacturing a CIS according to a second embodiment of the present invention.

As illustrated in FIG. 8, an interlayer insulation layer 42 can be formed on a semiconductor substrate having a plurality of light detecting devices (e.g., photodiode 41).

In an embodiment, the interlayer insulation layer 42 can be formed of multiple layers. In one embodiment, although not illustrated in the drawings, after forming one of the multiple interlayer insulation layers, a light blocking layer can be formed for preventing light from being incident to a region other than the photodiode 41 and then another interlayer insulation layer can be formed thereon.

A protective layer 43 can be formed on the interlayer insulation layer 42 to protect a device from moisture and scratching.

Then, a dyeable resist can be applied on the protective layer 43, and then exposed and developed to form an RGB color filter layer 44 to filter light in each wavelength range.

A planarization layer 45 can be formed on the color filter layer 44 to obtain planarization for focal length adjustment and formation of a lens layer.

As illustrated in FIG. 9, an insulation layer (e.g., an oxide layer or nitride layer) can be formed on the planarization layer 45, and can be selectively etched using a photolithography process to form an insulation pattern 46 corresponding to a center region of each photodiode 41.

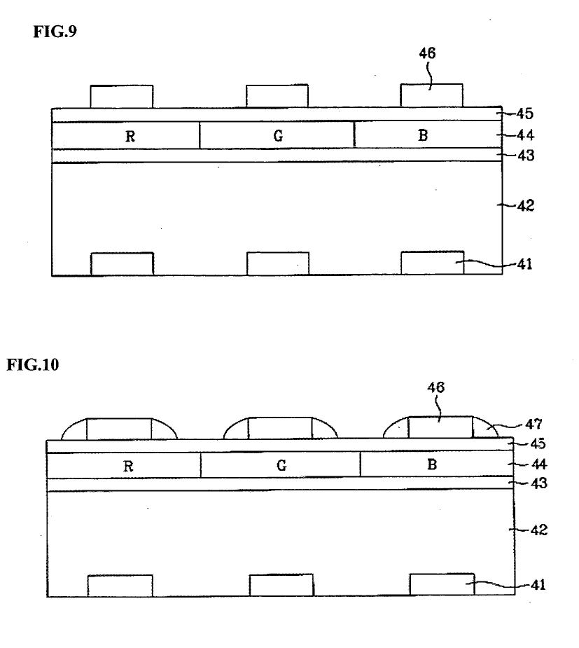

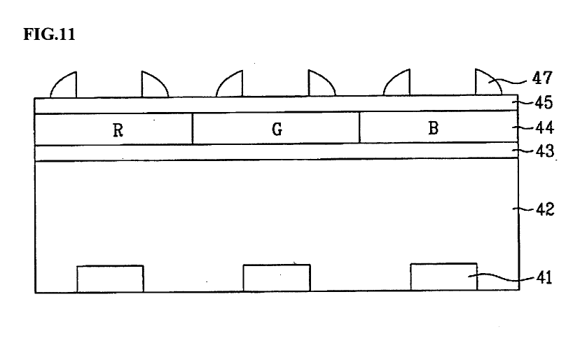

As illustrated in FIG. 10, a microlens material layer (e.g., a resist layer) can be formed on an entire surface of the semiconductor substrate having the insulation layer pattern 46. An etch back process can then be performed on the entire surface to form microlenses 47 in a sidewall shape on the sides of the insulation layer pattern 46.

As illustrated in FIG. 11, the insulation layer pattern 46 can be removed to form microlens 47 having an opening in a region corresponding to the photodiode 41.

At this point, the width of the opening varies according to the width of the photodiode 41, and may have the width identical to that of the photodiode 41.

In a specific embodiment, the opening can be formed in a width of 1 to 2 μm. The microlens 47 corresponding to the photodiode region is removed to improve light transmissivity. Therefore, incident light energy is maximized to improve the sensitivity of the image sensor.

In another embodiment, the microlens 47 can have an opening having a width broader than that of the photodiode 41.

Next, ultraviolet rays can be projected on the microlens 47 for hardening such that the microlens 47 can maintain the optimized radius of curvature. In one embodiment, a laser can be used to project UV rays on the microlens 47.

According to a method for manufacturing the CIS in the second embodiment, light energy outside the photodiode region can be induced into the photodiode through the microlens. The microlens has an opening in the photodiode region to improve light transmissivity. Therefore, the incident light energy is maximized to improve the sensitivity of an image sensor.

It will be apparent to those skilled in the art that various modifications and variations can be made in the present invention. Thus, it is intended that the present invention covers the modifications and variations of this invention provided they come within the scope of the appended claims and their equivalents.

I claim:

1. A CIS (complementary metal oxide silicon image sensor) comprising:
a photodiode formed on a substrate;
an interlayer insulation layer formed on the substrate including the photodiode;
a color filter layer formed on the interlayer insulation layer to pass light in a specific wavelength range; and
a microlens formed on the color filter layer, wherein the microlens has a predetermined opened region in a portion of the microlens corresponding to the location of the photodiode.

2. The CIS according to claim 1, wherein the microlens has a width wider than that of the photodiode.

3. The CIS according to claim 2, wherein the predetermined opened region has a width identical to that of the photodiode.

4. The CIS according to claim 2, wherein the predetermined opened region has a width of 1 to 2 μm.

5. A method for manufacturing a CIS (complementary metal oxide silicon image sensor), the method comprising:
forming an interlayer insulation layer on a substrate having a photodiode formed thereon;
forming a color filter layer on the interlayer insulation layer;
forming a microlens corresponding to the photodiode on the color filter layer; and
forming an opening in the microlens by selectively removing the microlens in a portion corresponding to the photodiode.

6. The method according to claim 5, wherein the opening has a width identical to that of the photodiode.

7. The method according to claim 6, wherein the opening has a width of 1 to 2 μm.

8. The method according to claim 5, wherein the microlens has a width wider than that of the photodiode.

9. The method according to claim 5, further comprising projecting UV rays onto the microlens having the opening to harden the microlens.

10. The method according to claim 5, wherein forming an opening in the microlens comprises:
forming a photosensitive film on the microlens;
patterning the photosensitive film to expose a portion of the microlens corresponding to the location of the photodiode;
removing the portion of the microlens to form the opening using the patterned photosensitive film as an etching mask; and
removing the patterned photosensitive film.

11. The method according to claim 5, further comprising forming a protective layer on the interlayer insulation layer.

12. A method for manufacturing a CIS (complementary metal oxide silicon image sensor), the method comprising:
forming an interlayer insulation layer on a substrate having a photodiode formed thereon;
forming a color filter layer on the interlayer insulation layer;
forming an insulation layer pattern corresponding to the location of the photodiode on the color filter layer;
forming microlens material on sides of the insulation layer pattern; and
removing the insulation layer pattern to form a microlens having an opening at a region corresponding to the location of the photodiode.

13. The method according to claim 12, wherein the opening has a width identical to that of the photodiode.

14. The method according to claim 13, wherein the opening has a width of 1 to 2 μm.

15. The method according to claim 12, wherein the microlens has a width wider than that of the photodiode.

16. The method according to claim 12, further comprising projecting UV rays on the microlens having the opening to harden the microlens.

17. The method according to claim 12, wherein forming an insulation layer pattern comprises:
forming an insulation layer on the color filter layer;
coating the insulation layer with a photosensitive film;
patterning the photosensitive film to expose the insulation layer at regions not corresponding to the location of the photodiode;
etching the exposed insulation layer using the patterned photosensitive film as an etching mask; and
removing the patterned photosensitive film.

18. The method according to claim 12, wherein forming microlens material on the sides of the insulation layer pattern comprises:
forming a microlens material layer on an entire surface of the substrate including the insulation layer pattern; and
etching back the microlens material layer to form microlens material on the sides of the insulation layer pattern.

19. The method according to claim 12, further comprising forming a protective layer on the interlayer insulation layer.
